(19) United States
(12) Patent Application Publication
(10) Pub. No.: US 2022/0171523 A1
(43) Pub. Date: Jun. 2, 2022

(54) SYSTEM, APPARATUS, AND METHOD FOR PROJECTING HOLIDAY DECORATIONS TO A DWELLING

(71) Applicants: Ricky Lee, Virginia Beach, VA (US); Darnell Thomas, Greenville, SC (US)

(72) Inventors: Ricky Lee, Virginia Beach, VA (US); Darnell Thomas, Greenville, SC (US)

(21) Appl. No.: 17/247,152

(22) Filed: Dec. 2, 2020

(51) Int. Cl. G06F 3/0484; G06F 3/0482; G06T 11/60; G03B 21/20

(52) U.S. Cl. CPC G06F 3/04847; G06F 3/0482; G06T 2200/24; G03B 21/2033; G06T 11/60

(57) ABSTRACT

A system, apparatus, and method for projecting holiday decorations onto a dwelling or structure. The home laser projected Christmas lighting system allows the homeowner to eliminate the risk of applying traditional holiday decorations, eliminates the purchase, storage, and maintenance/repair costs of conventional holiday decorations while obtaining a customized and personalized holiday motif for their dwelling. A method includes: taking a photograph of the dwelling; uploading the photograph of the dwelling to a computer; importing the photograph into a computer application configured to enable the user to apply a plurality of graphical representations of a holiday decoration to a design template image and saving the selected one or more holiday decorations as a projection image; and transferring the projection image to a laser projection device configured to project the projection image onto the dwelling at the points selected on the design template image.

### BACKGROUND OF THE INVENTION

The present invention relates to holiday decorations, and more particularly to outdoor holiday decorations to a home, dwelling, or other structure.

Currently, to achieve the full effect of outdoor holiday decorations, such as Christmas lighting on a home or dwelling, the homeowner must utilize a combination of lighting strings (bulbs), wreaths, candles, and other holiday themed laser projection. This can be very dangerous and time consuming as the homeowner often needs to climb a ladder to apply the decorations to their dwelling.

The installation, removal, storage of the decorative items can lead to damage of the decorative items. Bulbs may become broken, garland torn, and the decorative items may otherwise deteriorate due to the effects of weather and time. Likewise, the homeowner must also have storage space for holding the decorations for the next holiday season.

As can be seen, there is a need for an improved system, apparatus, and methods for decorating a dwelling with holiday decorations.

### SUMMARY OF THE INVENTION

In one aspect of the present invention, a system for projecting a user configurable holiday decoration on a dwelling is disclosed. The system includes a computer having a user interface, a display, and a non-volatile memory storage. A program product comprising machine-readable program code for causing, when executed, the computer to perform process steps. The steps include displaying a design template image of the dwelling on the display. A plurality of menu items is presented on the display. The plurality of menu items includes a graphical representation of a plurality of holiday decorative items. A user selection of a selected holiday decorative item from the plurality of holiday decorative items is received. A user application of the selected holiday decorative item to a desired location on the design template image is then received. The selected holiday decorative item and the desired location are saved as a projected image file in the non-volatile memory storage. A laser projection device is configured to receive the projected image file and project an image of the selected holiday decorative item on a portion of the dwelling corresponding to the desired location specified on the design template image.

In some embodiments, the plurality of holiday decorative items may include a lighting element; and a design feature associated with a selected holiday. The plurality of holiday decorative items may be a Christmas decoration selected from the group consisting of a light string, a wreath, a candle, a garland, and a caricature of a reindeer, a Santa Clause, an elf.

In some embodiments, the menu selection includes an attribute of the selected decorative item selected from the group consisting of a type of light, a color, a brightness, a temporal duration, and an effect. The computer may then receive a user selection of the attribute. The user may then apply the selected attribute to the selected decorative item.

In other embodiments, the system includes the computer receiving a photographic image of the dwelling and converting the photographic image of the dwelling to the design template image.

In other embodiments, the desired location corresponds to a structural element of the dwelling. In other embodiments, the desired location corresponds to a landscape element associated with the dwelling.

Other aspects of the invention include a method of projecting a user configurable holiday decoration on a dwelling. The method includes presenting, via software running on a computer, a design template image of the dwelling on a display of a computer. A plurality of menu items is presented on the display. The plurality of menu items includes a graphical representation of a plurality of holiday decorative items. The computer receives a user selection of a selected holiday decorative item from the plurality of holiday decorative items. A user application of the selected holiday decorative item to a desired location on the design template image is received via the computer. The selected holiday decorative item and the desired location are saved as a projected image file to a non-volatile memory storage device. The projected image file is transferred to a laser projection device configured to receive the projected image file from the non-volatile memory storage device. The laser projection device displays an image of the projected image file on a portion of the dwelling corresponding to the desired location specified on the design template image.

In some embodiments, the plurality of holiday decorative items is a lighting element and a design feature associated with a selected holiday. The plurality of holiday decorative items may be a Christmas decoration selected from the group consisting of a light string, a wreath, a candle, a garland, and a caricature of a reindeer, a Santa Clause, an elf.

The method may also include presenting an attribute selector in the plurality of menu items. The attribute selector is selected from the group consisting of a type of light, a color, a brightness, a temporal duration, and an effect of the selected decorative item. A user selection of the attribute is received, and the user applies the selected attribute to the selected decorative item.

Some embodiments of the method include receiving a photographic image of the dwelling and converting the photographic image of the dwelling to the design template image.

In some embodiments, the desired location corresponds to a structural element of the dwelling. The desired location may also correspond to a landscape element associated with the dwelling.

These and other features, aspects and advantages of the present invention will become better understood with reference to the following drawings, description and claims.

### BRIEF DESCRIPTION OF THE DRAWINGS

FIG. 1 is a flow describing how a user can create laser projected Christmas lighting customized to their home exterior.

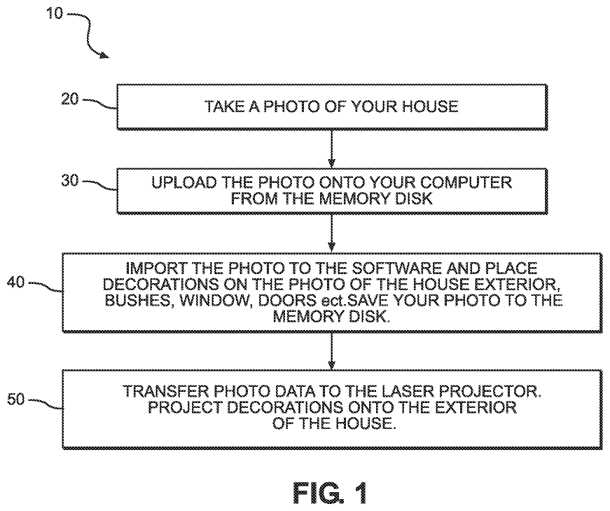

FIG. 2 is a diagram illustrating how a user can create laser projected Christmas lighting customized to their home exterior using a camera, a memory disk, a computer, a software, and a laser projection device.

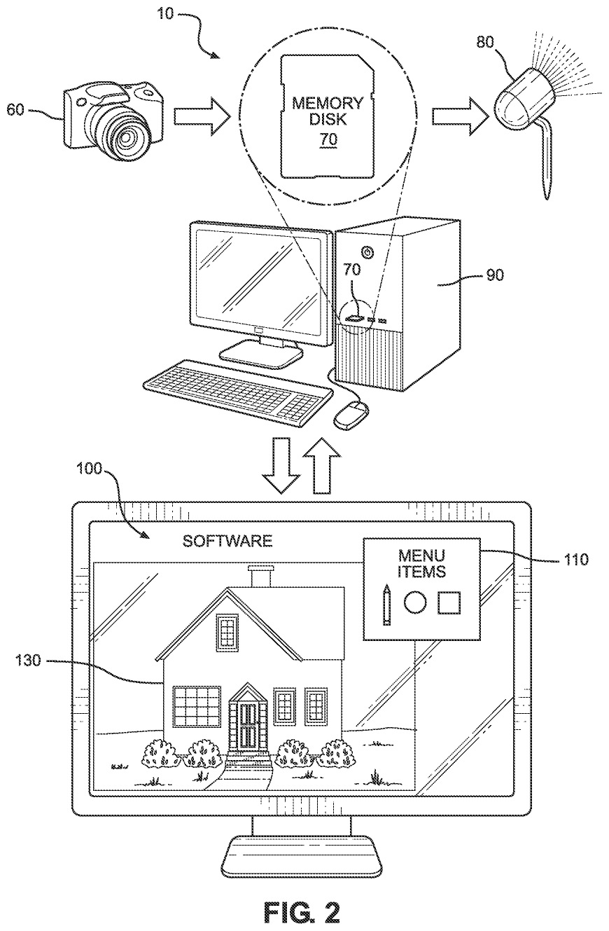

FIG. 3 is a photo of the home exterior which will be decorated inside the software.

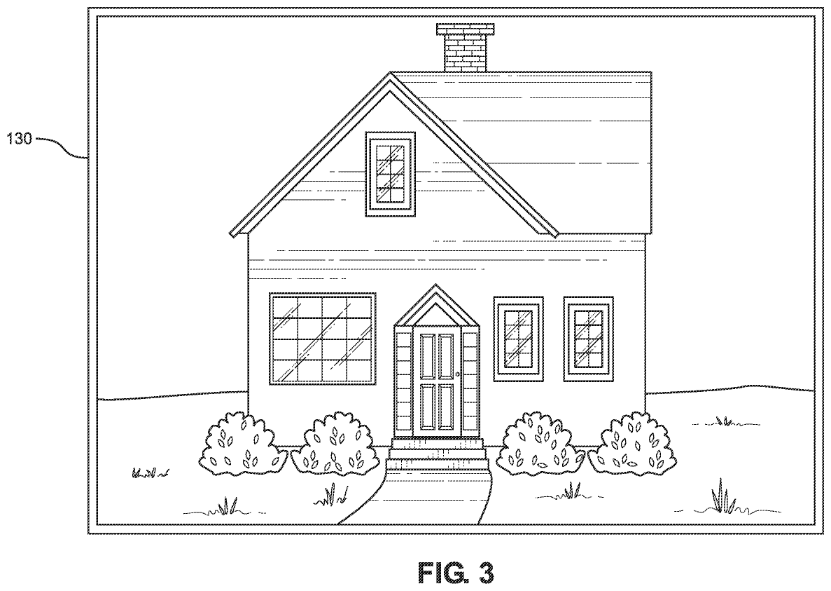

FIG. 4 is an in-use view of the home exterior with custom laser projected Christmas lighting.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, embodiments of the present invention provides a system, apparatus, and method for projecting holiday decorations onto a dwelling or structure. The home laser projected Christmas lighting system 10 of the present invention allows the homeowner to eliminate the risk of applying traditional holiday decorations, eliminates the purchase, storage, and maintenance/repair costs of conventional holiday decorations while obtaining a customized and personalized holiday motif for their dwelling.

A method according to aspects of the present invention may include the steps of: taking a photograph of the dwelling or structure to be decorated 20; uploading the photograph of the dwelling to a computer 30; importing the photograph into a computer application configured to enable the user to apply a plurality of graphical representations of a holiday decoration to a design template image 140 of the dwelling and saving the selected one or more holiday decorations as a projection image 40; and transferring the projection image to a laser projection device configured to project the projection image onto the dwelling at the points selected on the design template image 150.

A system according to aspects of the present invention may include, a camera 60; a non-transient memory storage device 70; is a laser projector 80; a computer 90; and a software application 100 loaded into the memory of the computer 90.

The software application 100 provides a user interface allowing the user to select from a plurality of menu items 110, with each of the plurality of menu items 110 corresponding to a plurality of holiday decorative items or an attribute of a selected decoration. The plurality of holiday decorative items may be a lighting, a feature associated with a selected holiday, and the like. By way of non-limiting example, the plurality of holiday decorative items may be Christmas decorations, selected from the group consisting of a light string, wreaths, candles, garland, and caricatures of reindeer, Santa Clause, elves, and the like. The attribute of the selected decorative item may be selected from the group consisting of a type of light, a color, a brightness, a temporal duration, and an effect.

The temporal duration may allow the homeowner to change one or more other attributes over time to vary the look of the selected decorative motif over a user configured predetermined temporal period. The effect may include a flashing, a sequencing, a flicker, a relative motion, and other effects that may be programmed to one or more of the lights or other decorative items.

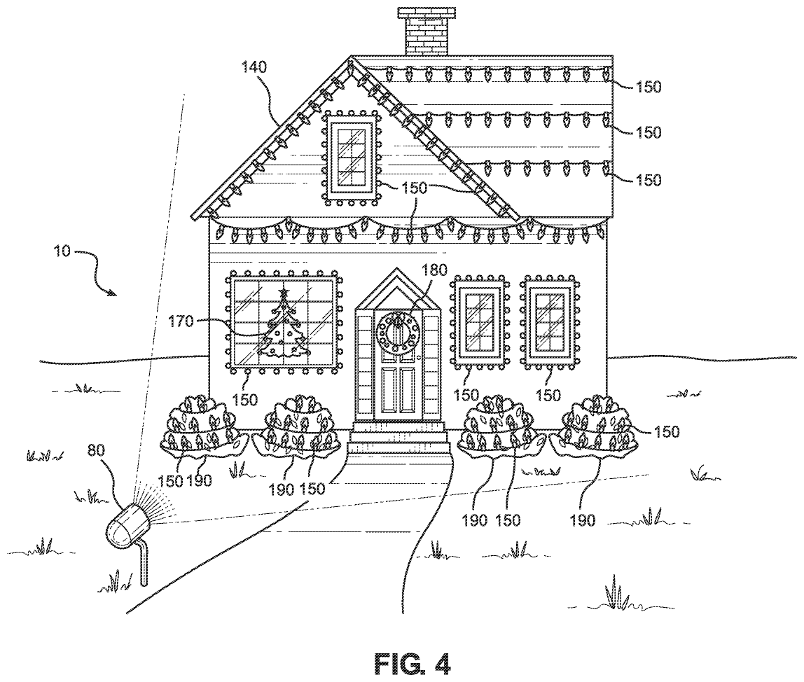

In the example shown in FIG. 4, with the photograph of the house 130 loaded into the user interface as a design template image 140, the user may apply a light element 150 to one or more structural features of the house 150 or a landscape feature 190 in a yard of the house 130. A decorative element such as a Christmas tree 170 may be projected on a window, while a wreath 180 may also be projected on a door of the dwelling 140.

As indicated previously, once the user has applied the plurality of decorative items to the design template image 140, the user saves the selected one or more holiday decorations as the projection image. The projection image is transferred to the laser projector 80, such as a via a USB stick, memory card, or a wireless transfer of the projection image to a memory of the laser projector 80. Preferably, the laser projector is positioned at a point corresponding to the location where the photograph of the house was taken. One or more of the software application and the laser projector 80 may have a plurality of controls to adjust the projection image to the house 140 to accommodate for variations in one of the focal length or a projection angle between the photograph 130 of the house 140 and the positioning of the laser projector 80 relative to the house 140.

The system of the present invention may include at least one computer with a user interface. The computer may include any computer including, but not limited to, a desktop, laptop, and smart device, such as, a tablet and smart phone. The computer includes a program product including a machine-readable program code for causing, when executed, the computer to perform steps. The program product may include software which may either be loaded onto the computer or accessed by the computer. The loaded software may include an application on a smart device. The software may be accessed by the computer using a web browser. The computer may access the software via the web browser using the internet, extranet, intranet, host server, internet cloud and the like.

The computer-based data processing system and method described above is for purposes of example only, and may be implemented in any type of computer system or programming or processing environment, or in a computer program, alone or in conjunction with hardware. The present invention may also be implemented in software stored on a non-transitory computer-readable medium and executed as a computer program on a general purpose or special purpose computer. For clarity, only those aspects of the system germane to the invention are described, and product details well known in the art are omitted. For the same reason, the computer hardware is not described in further detail. It should thus be understood that the invention is not limited to any specific computer language, program, or computer. It is further contemplated that the present invention may be run on a stand-alone computer system, or may be run from a server computer system that can be accessed by a plurality of client computer systems interconnected over an intranet network, or that is accessible to clients over the Internet. In addition, many embodiments of the present invention have application to a wide range of industries. To the extent the present application discloses a system, the method implemented by that system, as well as software stored on a computer-readable medium and executed as a computer program to perform the method on a general purpose or special purpose computer, are within the scope of the present invention. Further, to the extent the present application discloses a method, a system of apparatuses configured to implement the method are within the scope of the present invention.

It should be understood, of course, that the foregoing relates to exemplary embodiments of the invention and that modifications may be made without departing from the spirit and scope of the invention as set forth in the following claims.

What is claimed is:

1. A system for projecting a user configurable holiday decoration on a dwelling, comprising:
a computer having a user interface, a display, and a non-volatile memory storage; and
a program product comprising machine-readable program code for causing, when executed, the computer to perform process steps:
displaying a design template image of the dwelling on the display;
presenting a plurality of a plurality of menu items on the display, the plurality of menu items including a graphical representation of a plurality of holiday decorative items;
receiving a user selection of a selected holiday decorative item from the plurality of holiday decorative items;
receiving a user application of the selected holiday decorative item to a desired location on the design template image;
saving the selected holiday decorative item and the desired location as a projected image file in the non-volatile memory storage; and
a laser projection device configured to receive the projected image file and project an image of the selected holiday decorative item on a portion of the dwelling corresponding to the desired location specified on the design template image.

2. The system of claim 1, further wherein the plurality of holiday decorative items comprises:
a lighting element; and
a design feature associated with a selected holiday.

3. The system of claim 1, wherein the plurality of holiday decorative items is a Christmas decoration selected from the group consisting of a light string, a wreath, a candle, a garland, and a caricatures of a reindeer, a Santa Clause, an elf.

4. The system of claim 1, the menu items further comprising:
an attribute selected from the group consisting of a type of light, a color, a brightness, a temporal duration, and an effect;
receiving a user selection of the attribute; and
applying the selected attribute to the selected holiday decorative item.

5. The system of claim 1, further comprising:
receiving a photographic image of the dwelling; and
converting the photographic image of the dwelling to the design template image.

6. The system of claim 1, wherein the desired location corresponds to a structural element of the dwelling.

7. The system of claim 6, wherein the desired location corresponds to a landscape element associated with the dwelling.

8. A method of projecting a user configurable holiday decoration on a dwelling, comprising:
presenting, via software running on a computer, a design template image of the dwelling on a display of the computer;
presenting, via software running on the computer, a plurality of menu items on the display, the plurality of menu items including a graphical representation of a plurality of holiday decorative items;
receiving a user selection of a selected holiday decorative item from the plurality of holiday decorative items;
receiving a user application of the selected holiday decorative item to a desired location on the design template image;
saving the selected holiday decorative item and the desired location as a projected image file to a non-volatile memory storage device;
transferring the projected image file to a laser projection device configured to receive the projected image file from the non-volatile memory storage device; and
projecting, by the laser projection device, an image of the projected image file on a portion of the dwelling corresponding to the desired location specified on the design template image.

9. The method of claim 8, wherein the plurality of holiday decorative items comprises:
a lighting element; and
a design feature associated with a selected holiday.

10. The method of claim 8, wherein the plurality of holiday decorative items is a Christmas decoration selected from the group consisting of a light string, a wreath, a candle, a garland, and a caricatures of a reindeer, a Santa Clause, an elf.

11. The method of claim 8, further comprising:
presenting an attribute selector in the plurality of menu items, the attribute selector selected from the group consisting of a type of light, a color, a brightness, a temporal duration, and an effect of the selected holiday decorative item;
receiving a user selection of the attribute; and
applying the selected attribute to the selected holiday decorative item.

12. The method of claim 8, further comprising:
receiving a photographic image of the dwelling; and
converting the photographic image of the dwelling to the design template image.

13. The method of claim 8, wherein the desired location corresponds to a structural element of the dwelling.

14. The method of claim 13, wherein the desired location corresponds to a landscape element associated with the dwelling.
